(19) United States
(12) Patent Application Publication
(10) Pub. No.: US 2025/0244660 A1
(43) Pub. Date: Jul. 31, 2025

(54) SEMICONDUCTOR DEVICE MANUFACTURING METHOD

(71) Applicant: Samsung Electronics Co., Ltd., Suwon-si (KR)

(72) Inventors: Inbeom YIM, Suwon-si (KR); Seungyoon LEE, Suwon-si (KR); Jeongjin LEE, Suwon-si (KR); Chan HWANG, Suwon-si (KR); Heonju LEE, Suwon-si (KR)

(73) Assignee: Samsung Electronics Co., Ltd., Suwon-si (KR)

(21) Appl. No.: 18/824,112

(22) Filed: Sep. 4, 2024

(30) Foreign Application Priority Data
Jan. 26, 2024 (KR) 10-2024-0012447

(51) Int. Cl. G03F 1/72; G03F 7/00

(52) U.S. Cl. CPC G03F 1/72; G03F 7/70633

(57) ABSTRACT

A semiconductor device manufacturing method includes determining whether or not a reticle writing correction needs to be applied to a mask for an exposure process, when determining that the reticle writing correction needs to be applied, manufacturing the mask to which the reticle writing correction is applied by using the mask to which the reticle writing correction is applied, measuring an overlay and performing a correction based on the basis of on the measured overlay, determining whether or not a value of the measured overlay is greater than a specification, and when the value of the measured overlay is not greater than the specification, performing a subsequent process.

### CROSS-REFERENCE TO RELATED APPLICATION

This application is based on and claims priority under 35 U.S.C. § 119 to Korean Patent Application No. 10-2024-0012447, filed on Jan. 26, 2024, in the Korean Intellectual Property Office, the disclosure of which is incorporated by reference herein in its entirety.

### BACKGROUND

The inventive concepts relate to semiconductor devices manufacturing method.

An example of a process for manufacturing semiconductor devices is an exposure process in which exposure is performed on respective layers included in semiconductor substrates. With the recent miniaturization and high integration of semiconductor devices, the impact of minute errors in exposure processes for respective layers on the quality of semiconductor products has increased. Accordingly, various technologies for precisely simulating exposure processes have been provided.

### SUMMARY

The inventive concepts provide semiconductor device manufacturing methods having improved reliability.

According to an example embodiment of the inventive concepts, a semiconductor device manufacturing method may include determining whether or not a reticle writing correction needs to be applied to a mask for an exposure process, when determining that the reticle writing correction needs to be applied, manufacturing the mask to which the reticle writing correction is applied, by using the mask to which the reticle writing correction is applied, measuring an overlay and performing a correction based on the overlay, determining whether or not a value of the overlay is greater than a specification, and when the value of the overlay is not greater than the specification, performing a subsequent process.

According to an example embodiment of the inventive concepts, a semiconductor device manufacturing method may include performing a first alignment with respect to a scanner configured to perform an exposure process on a substrate, performing a first exposure on the substrate through the scanner that has been aligned by performing the first alignment, measuring an alignment correction parameter while the scanner performs the first exposure on the substrate, identifying an asymmetric scale from the alignment correction parameter, determine whether or not the identified asymmetric scale is greater than a specification, when the asymmetric scale is greater than the specification, determining that a reticle writing correction needs to be applied to a mask for an exposure process and manufacturing the mask to which the reticle writing correction is applied, measuring an overlay and performing a correction based on the overlay through the mask to which the reticle writing correction is applied, determining whether or not a value of the overlay is greater than the specification, when the value of the overlay is not greater than the specification, measuring a skew value of a critical dimension through the scanner, determining whether or not the skew value of the critical dimension is greater than the specification, and when the skew value of the critical dimension is not greater than the specification, performing a subsequent process, wherein, when viewed on a plane, the asymmetric scale includes Y-axis skews facing each other toward a central axis of the substrate in a first direction and X-axis skews opposing each other and moving away from a central axis in a second direction orthogonal to the first direction.

According to an example embodiment of the inventive concepts, a semiconductor device manufacturing method may include determining whether or not a reticle writing correction needs to be applied to a mask for an exposure process, when determining that the reticle writing correction needs to be applied, manufacturing the mask to which the reticle writing correction is applied, measuring an overlay and performing a correction based on overlay, through the mask to which the reticle writing correction is applied, determining whether or not a value of the overlay is greater than a specification, when the value of the overlay is not greater than the specification, measuring a skew value of a critical dimension, determining whether or not the skew value of the critical dimension is greater than the specification, and when the skew value of the critical dimension is not greater than the specification, performing a subsequent process, wherein the determining of whether or not the reticle writing correction needs to be applied includes performing a first alignment with respect to a scanner, performing a first exposure on a substrate through the scanner that has been aligned by performing the first alignment, measuring an alignment correction parameter while the scanner performs the first exposure on the substrate, identifying an asymmetric scale from the alignment correction parameter, and determining whether or not the identified asymmetric scale is greater than the specification, and when the asymmetric scale is greater than the specification, determining that the reticle writing correction needs to be applied to the mask for the exposure process, the measuring of the overlay and performing of the correction based on the overlay includes performing a second alignment with respect to the scanner, feeding forward the alignment correction parameter to the scanner, performing a second exposure on the substrate through the scanner that has been fed forward the alignment correction parameter, and measuring the overlay through the scanner, and when a value of the asymmetric scale is defined as 1, a magnitude of the reticle writing correction is x (wherein 0<x<1), and a value of the alignment correction parameter fed forward to the scanner is 1-x.

### BRIEF DESCRIPTION OF THE DRAWINGS

Example embodiments will be more clearly understood from the following detailed description taken in conjunction with the accompanying drawings in which:

FIG. 1 is a flowchart of a semiconductor device manufacturing method according to an example embodiment;

FIG. 2 is a flowchart illustrating in detail operation S110 of determining whether or not a reticle writing correction needs to be applied in a semiconductor device manufacturing method, according to an example embodiment;

FIG. 3 is a flowchart illustrating in detail operation S140 of measuring and correcting an overlay through a mask to which a reticle writing correction is applied in a semiconductor device manufacturing method, according to an example embodiment;

FIG. 4 is a view schematically illustrating a shape of a lower substrate of a substrate before a reticle writing correction in a semiconductor device manufacturing method, according to an example embodiment;

FIG. 5 is a plan view illustrating an asymmetric scale of a lower plate with respect to an upper plate of FIG. 4;

FIG. 6 is a view schematically illustrating a shape of a lower plate of a substrate after a reticle writing correction in a semiconductor device manufacturing method, according to an example embodiment;

FIG. 7 is a plan view illustrating an asymmetric scale of a lower plate of FIG. 6 with respect to an upper plate of FIG. 6;

FIG. 8 is a plan view illustrating an asymmetric scale measured by a scanner, in a semiconductor device manufacturing method, according to an example embodiment;

FIG. 9 is a conceptual view of a semiconductor device manufacturing method according to an example embodiment;

FIGS. 10A to 10C are views sequentially illustrating performing a Y-axis skew correction in a semiconductor device manufacturing method, according to an example embodiment;

FIGS. 11A to 11E are views sequentially illustrating performing an X-axis skew correction in a semiconductor device manufacturing method, according to an example embodiment; and

FIGS. 12A to 12E are views illustrating a skew value of a critical dimension with respect to a moving standard deviation.

### DETAILED DESCRIPTION

Some example embodiments will be illustrated in the drawings and described in detail in the description. However, this is not intended to limit the present example embodiments to particular disclosure forms. The example embodiments described below are merely illustrative, and various modifications may be made from the example embodiments.

The use of all examples or example terms is simply intended to describe the spirit of the inventive concepts in detail, and the scope of the inventive concepts are not limited by the examples or example terms unless limited by claims.

Unless otherwise specified below, in the description, a vertical direction may be defined as a Z direction, and each of a first direction and a second direction may be defined as a vertical direction perpendicular to the Z direction. The first direction may be referred to as X, and the second direction may be referred to as Y. A vertical level may refer to a height level along the vertical direction Z. A horizontal width may refer to a length in a horizontal direction (X and/or Y), and a vertical length may refer to a length in the vertical direction Z.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the term “about,” “substantially” or “approximately” is used in this specification in connection with a numerical value, it is intended that the associated numerical value includes a manufacturing or operational tolerance (e.g., ±10%) around the stated numerical value. Moreover, when the word “about,” “substantially” or “approximately” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

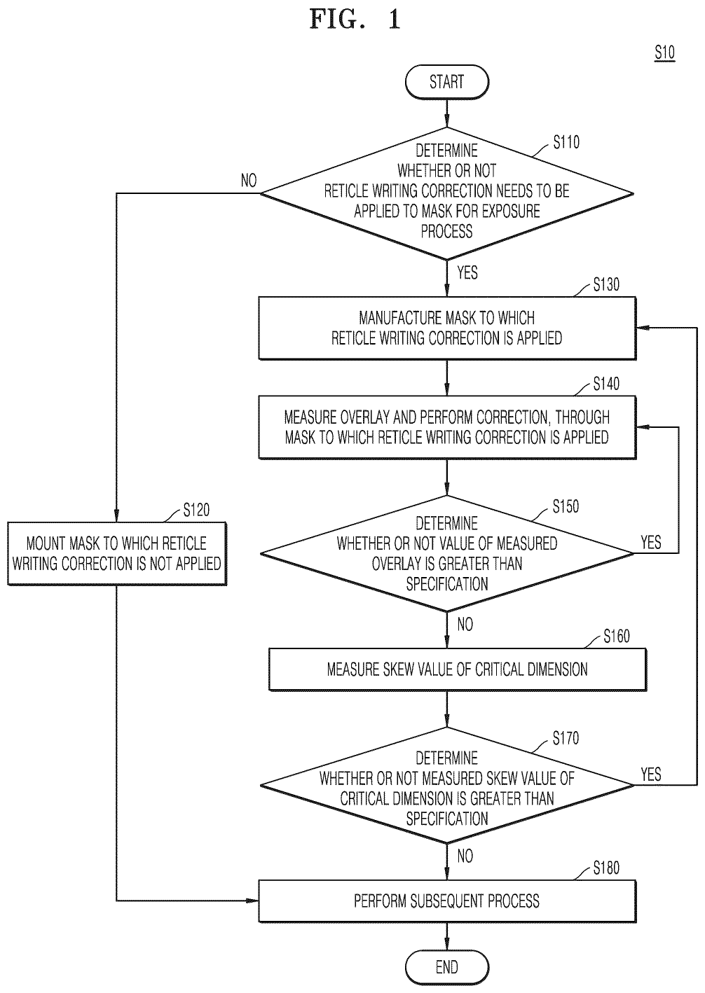

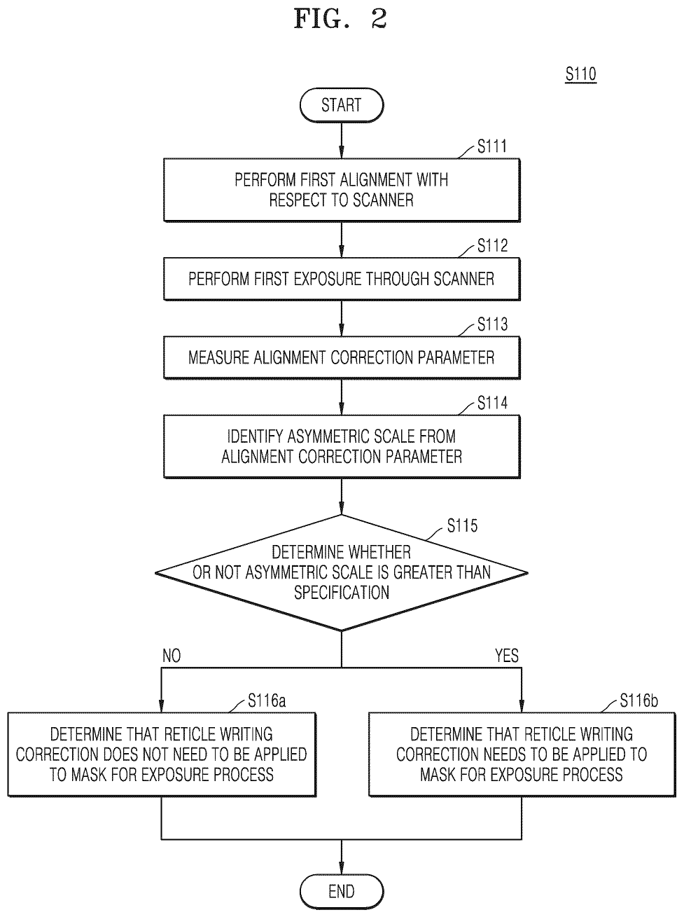

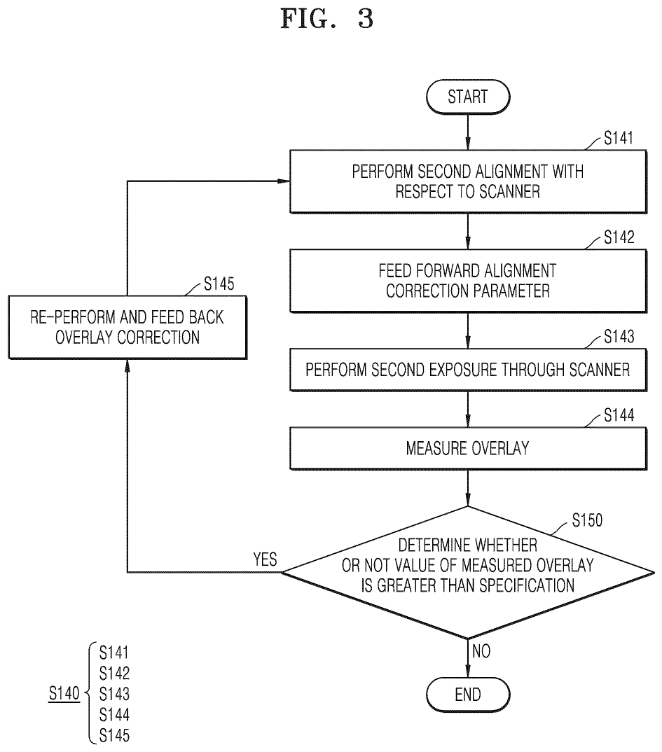

FIG. 1 is a flowchart of a semiconductor device manufacturing method according to an example embodiment. FIG. 2 is a flowchart illustrating in detail operation S110 of determining whether or not a reticle writing correction needs to be applied in a semiconductor device manufacturing method, according to an example embodiment. FIG. 3 is a flowchart illustrating in detail operation S140 of measuring and correcting an overlay through a mask to which a reticle writing correction is applied in a semiconductor device manufacturing method, according to an example embodiment.

Referring to FIGS. 1, 2, and 3, a semiconductor device manufacturing method S10 may include operation S110 of determining whether or not a reticle writing correction needs to be applied to a mask for an exposure process. In the present disclosure, a reticle may correspond to a mask used when performing an exposure process on a substrate. In the present disclosure, the reticle writing correction may refer to a correction for reducing a skew value of a critical dimension caused by a scanner described below, rather than a correction that is pre-reflected on a mask to correct a higher-order component of an overlay.

The operation S110 may include the operation S111 of performing a first alignment by the scanner. The substrate may include a plurality of layers, and the scanner may perform the operation S111 a plurality of times with respect to each of the plurality of layers. In the operation S111, the scanner may perform only an alignment by a default value, and when an additional alignment is needed, the additional alignment may be performed in a subsequent operation.

The operation S110 may include operation S112 of performing a first exposure on the substrate through the aligned scanner after performing the operation S111. The operation S112 may be performed while the mask that is not aligned is mounted. The substrate may be divided into a plurality of virtual regions. Each of the plurality of regions may be defined as a shot. The scanner may perform an exposure independently and sequentially for respective shots rather than performing an exposure on the entire area of the substrate at a time.

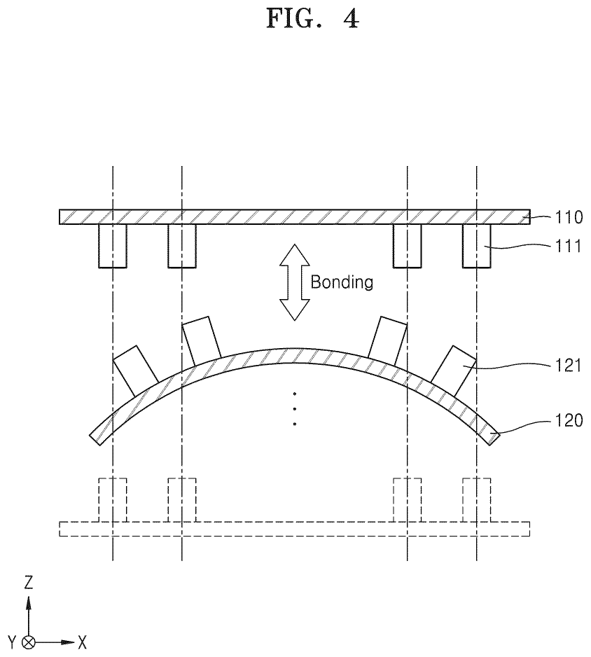

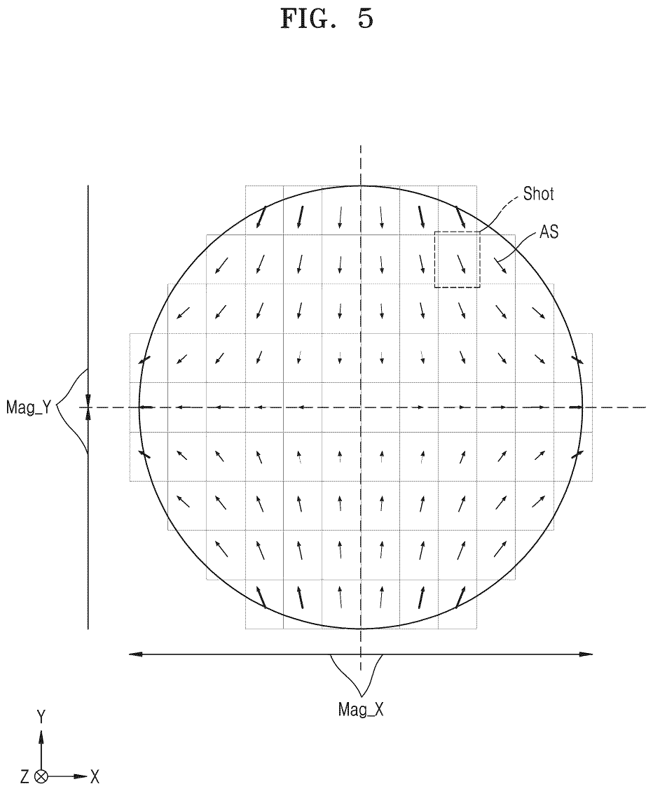

The operation S110 may include operation S113 of measuring an alignment correction parameter while the scanner performs the exposure on the substrate and operation S114 of identifying an asymmetric scale from the measured alignment correction parameter. In an example embodiment, the asymmetric scale may refer to a magnitude of a phase difference in a position of an alignment key on each of an upper plate and a lower plate of a substrate, which changes when wafer warpage occurs due to a thermal process or the like in a process of bonding the upper plate and the lower plate for forming the substrate including the upper plate and the lower plate. The detailed description thereof is given with reference to FIGS. 4 to 7. The asymmetric scale may include an X-axis skew Mag_X and a Y-axis skew Mag_Y of FIG. 5, and the detailed description thereof is given with reference to FIG. 5.

The operation S110 may include operation S115 of determining whether or not the identified asymmetric scale is greater than a specification. The specification may be determined differently according to characteristics of the substrate, a size of the substrate, a thickness of a slit of the scanner, and the like.

The operation S110 may include operation S116a of determining that the reticle writing correction does not need to be applied to the mask for the exposure process when the asymmetric scale is not greater than the specification in the operation S115. The operation S110 may include operation S116b of determining that the reticle writing correction needs to be applied to the mask for the exposure process when the asymmetric scale is greater than the specification in the operation S115. Operation S10 may include operation S120 of mounting the mask to which the reticle writing correction is not applied, which is performed when operation S116a is performed. When operation S120 is performed, operation S180 of performing a subsequent process may be performed. Operation S180 may include various processes. For example, a subsequent semiconductor processes may include a deposition process, an etching process, an ion process, a cleaning process, and the like. Also, the subsequent semiconductor process may include a singulation process for individualizing a wafer into respective semiconductor chips, a test process for testing the semiconductor chips, and a packaging process for packaging the semiconductor chips. A semiconductor device may be completed through the subsequent semiconductor process on the wafer.

Operation S10 may include operation S130 of manufacturing the mask to which the reticle writing correction is applied, which is performed when operation S116b is performed. As illustrated in the flowchart, operation S130 may be performed before operation S140 of measuring and correcting the overlay through the mask to which the reticle writing correction is applied. Therefore, operation S110 of determining whether or not the reticle writing correction needs to be applied and operation S130 of manufacturing the mask to which the reticle writing correction is applied may not be for correcting the overlay. Operations S110 and S130 may be performed to pre-align the scanner to reduce an amount of alignment of the scanner described below.

Operation S10 may include operation S140 of measuring and correcting the overlay through the mask to which the reticle writing correction is applied. Operation S140 may include operation S141 of performing a second alignment with respect to the scanner. A magnitude and direction of the second alignment in operation S141 may be different from a magnitude and direction of the first alignment in operation S111. Operations S111 and S141 may be performed by the same scanner. Operations S111 and S141 may be performed on the same layer. Therefore, operations S111 and S141 may be sequentially performed on one layer. In an example embodiment, when the substrate has a plurality of layers, operations S111 and S141 may be performed a plurality of times on one substrate.

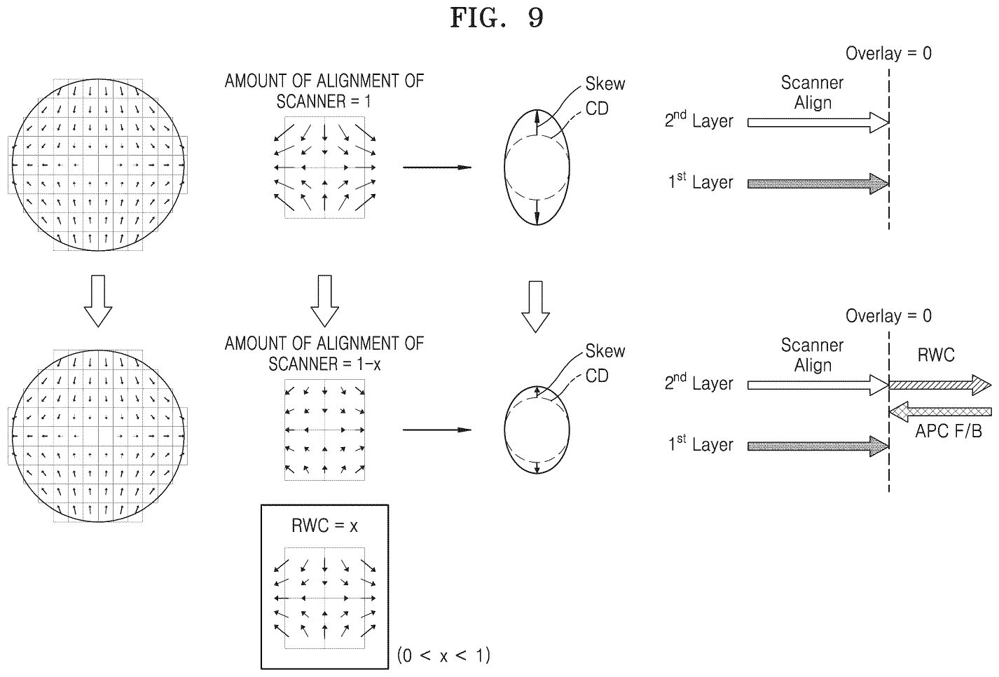

Operation S140 may include operation S142 of feeding forward the alignment correction parameter. The sum of a value of the fed forward alignment correction parameter and a value of the reticle writing correction in operations S110 and/or S130 may be a value of the asymmetric scale identified in operation S114. The value of the alignment correction parameter value fed forward may be proportional to a skew value of a critical dimension described below. Therefore, when the value of the reticle writing correction is obtained, the skew value of the critical dimension described below may be reduced. The detailed description thereof is given with reference to FIG. 9.

Operation S140 may include operation S143 of performing a second exposure on the substrate through the scanner fed forward in operation S142. A magnitude and direction of the second exposure in operation S143 may be different from a magnitude and direction of the first exposure in operation S112. Operations S143 and S112 may be performed by the same scanner. Operations S143 and S112 may be performed on the same layer. Therefore, operations S143 and S112 may be sequentially performed on one layer. In an example embodiment, when the substrate has the plurality of layers, operations S143 and S112 may be performed a plurality of times on one substrate.

Operation S140 may include operation S144 of measuring the overlay. Operation S10 may include operation S150 of determining whether or not a value of the measured overlay is greater than the specification. Operation S140 may include re-performance and overlay correction feedback operation S145 performed when the value of the measured overlay is greater than the specification in operation S150. Overlay correction feedback may be performed by advanced process control (APC). In semiconductor devices or a semiconductor wafer including the semiconductor devices, patterns of adjacent layers need to be accurately aligned. Accordingly, overlay measurement may be performed to align the patterns. For example, an overlay may refer to the degree of misalignment between two layers when an exposure process is performed on a previous layer of a semiconductor substrate and after several processes, the exposure process is performed again on a next layer or a current layer. Meanwhile, correcting a relative location between layers may be referred to as an overlay correction, and overlay measurement may be performed for such overlay correction. The overlay measurement may refer to measuring the degree of misalignment between layers (e.g., overlay misalignment or an overlay error).

When operation S145 is performed, operation S141 may be re-performed. With respect to re-performing, operations S141 to S144 may be performed on the basis of an overlay correction value fed back in operation S145.

Operation S10 may include operation S150 of determining whether or not the value of the measured overlay is greater than the specification, and operation S140 may be re-performed when the value of the overlay is greater than the specification in operation S150 until the value of the overlay becomes less than the specification.

Operation S10 may include operation S160 of measuring the skew value of the critical dimension, which is performed when the value of overlay is less than the specification in operation S150. A critical dimension may refer to a line width and distance of the smallest circuit, and/or a size of a hole. In the present disclosure, a critical dimension may be the size of the hole. Further, the skew value in the inventive concept may refer to a difference in an aspect ratio of each layer that is a ratio between a long axis and short axis of the size of the hole.

Operation S10 may include operation S170 of determining whether or not the skew value of the critical dimension measured in operation S160 is greater than the specification. The specification may be determined differently according to the characteristics of the substrate, the size of the substrate, the thickness of the slit of the scanner, and the like.

When the measured skew value of the critical dimension is determined to be greater than the specification in operation S170, operation S130 may be re-performed until the skew value of the critical dimension becomes less that the specification. When the measured skew value of the critical dimension is determined to be less than the specification in operation S170, operation S180 of performing the subsequent process may be performed.

FIG. 4 is a view schematically illustrating a shape of a lower substrate of a substrate before a reticle writing correction in a semiconductor device manufacturing method, according to an example embodiment.

Referring to FIG. 4, a substrate may be formed of a plurality of layers. In an example embodiment, the substrate may include an upper plate 110 and a lower plate 120. The upper plate 110 may include a plurality of upper plate alignment keys 111. The lower plate 120 may include a plurality of lower plate alignment keys 121. The upper plate 110 and the lower plate 120 may be attached to each other through a bonding process. When performing the bonding process, a thermal process in which heat is applied to the lower plate 120 may be performed. Dotted lines in FIG. 4 may indicate a shape of the lower plate 120 before the thermal process is performed. Before the thermal process is performed, the shape of the lower plate 120 may be flat on the basis of an axis in each of a first direction X and a second direction Y orthogonal to the first direction X. In addition, the upper alignment keys 111 and the lower alignment keys 121 may be on the same axis in the third direction Z that is simultaneously orthogonal to the first direction Xand the second direction Y. After the thermal process is performed, the shape of the lower plate 120 may not be flat and wafer warpage may occur therein, when viewed from the axis in the second direction Y. Although not shown in FIG. 5, after the thermal process is performed, the wafer warpage may occur in the shape of the lower plate 120 in the same manner even on the basis of the axis in the first direction X. When the wafer warpage occurs, the upper plate alignment keys 111 and the lower plate alignment keys 121 may be misaligned with each other, on the same axis in the third direction Z.

FIG. 5 is a plan view illustrating an asymmetric scale of a lower plate with respect to an upper plate of FIG. 4.

Referring to FIG. 5, a scanner, which performs operation S110, may divide a circular substrate into virtual regions and sequentially measure the respective regions. As described above, each of the regions may be defined as a shot. When operations S111 to S114 are performed with respect to each shot, an asymmetric scale AS may be identified. An arrow shown in FIG. 5 may correspond to the asymmetric scale AS. Accordingly, the asymmetric scale AS may be a vector value measured for each shot.

The asymmetric scale AS may include an X-axis skew Mag_X and a Y-axis skew Mag_Y. In more detail, the Y-axis skew Mag_Y may face each other toward a central axis of the substrate in a first direction X, and the X-axis skew Mag_X may be opposite to each other and away from a central axis of the substrate in a second direction. Therefore, the X-axis skew Mag_X may be a vector value toward the outside of the substrate, and the Y-axis skew Mag_Y may be a vector value toward a center of the substrate. Magnitudes of the X-axis skew Mag_X and the Y-axis skew Mag_Y may be different from each other. The asymmetric scale AS may be formed with a sum of respective vectors of the X-axis skew Mag_X and the Y-axis skew Mag_Y.

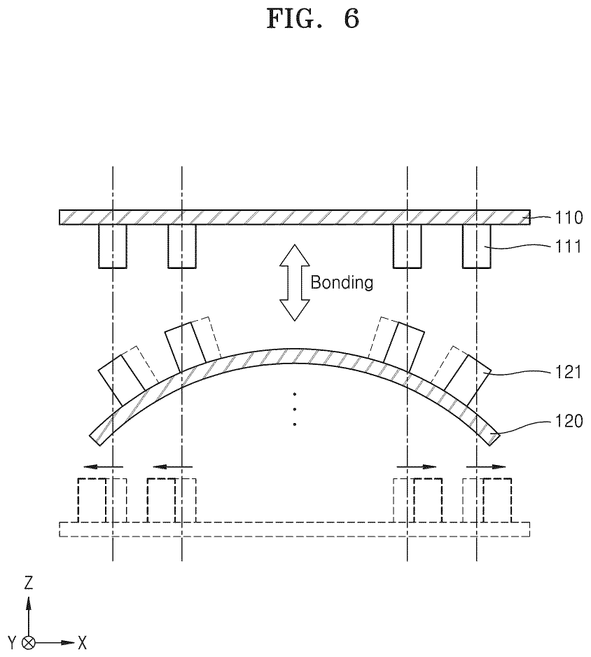

FIG. 6 is a view schematically illustrating a shape of a lower plate of a substrate after a reticle writing correction in a semiconductor device manufacturing method, according to an example embodiment.

Referring to FIG. 6, by performing operations S130 and S140, a scanner may perform a scan and exposure while lower plate alignment keys 121 located on a lower plate 120 are aligned. Solid line lower plate alignment keys 121, which are arranged on an upper surface of the lower plate 120 indicated by a solid line, may not be actual locations, but may be scan locations after a correction of a skew is performed. Dotted line lower plate alignment keys 121, which are arranged on the upper surface of the lower plate 120 indicated by the solid line, may be actual locations. A scan may be performed as though dotted line lower plate alignment keys arranged on an upper surface of a lower plate indicated by a solid line are moved outwards. The upper plate alignment keys 111, and the solid line lower plate alignment keys 121 scanned as though being at aligned locations may be formed on the same axis in a third direction Z. However, in this case, the actual lower plate alignment keys 121 may not be moved, but may be only scanned as though being moved.

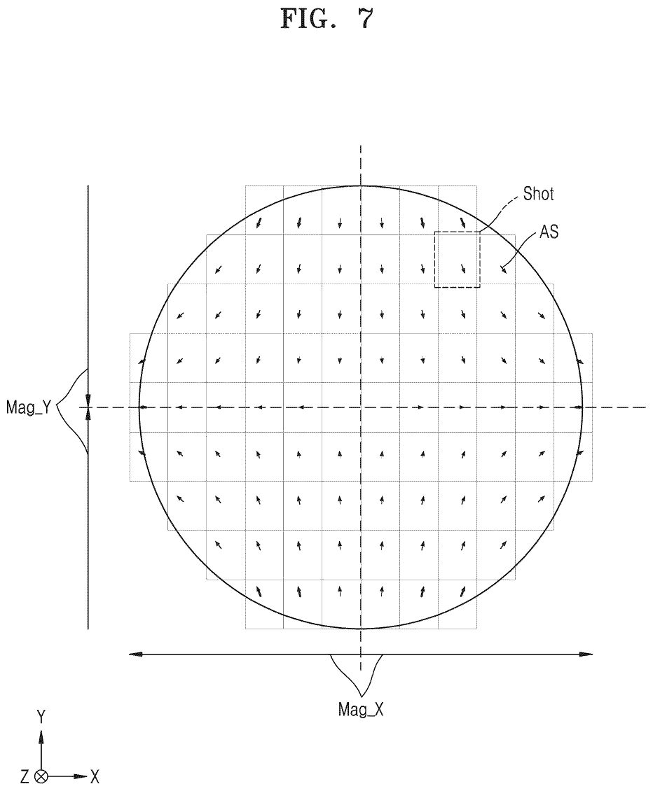

FIG. 7 is a plan view illustrating an asymmetric scale of a lower plate of FIG. 6 with respect to an upper plate of FIG. 6. The description of FIG. 7, which is the same as the description of FIG. 5, is omitted.

Referring to FIG. 7, a length of an arrow indicating a vector value of an asymmetric scale AS may be less than a length of an arrow in FIG. 5. In the case of a scan after being aligned, a magnitude of the asymmetric scale AS may be reduced. The magnitude of the asymmetric scale AS may decrease toward a center of a substrate. The magnitude of the asymmetric scale AS may increase toward the outside of the substrate, but even in this case, the magnitude of the asymmetric scale AS after being aligned may be formed to be less than the size of the asymmetric scale AS shown in FIG. 5. The asymmetric scale AS of FIG. 7 may include an X-axis skew Mag_X and a Y-axis skew Mag_Y. However, magnitudes of the X-axis skew Mag_X and the Y-axis skew Mag_Y may be less than the magnitudes of the X-axis skew Mag_X and the Y-axis skew Mag_Y of FIG. 5, respectively.

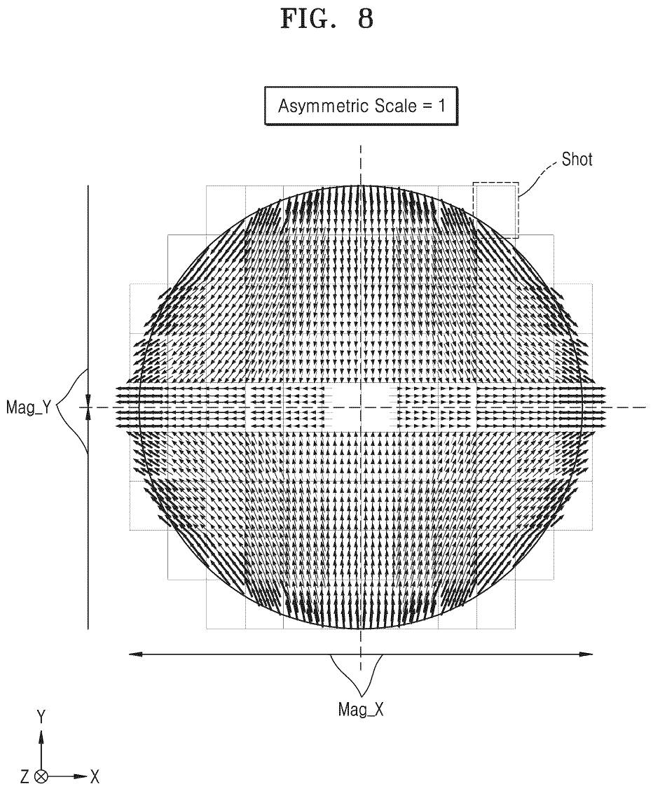

FIG. 8 is a plan view illustrating an asymmetric scale measured by a scanner, in a semiconductor device manufacturing method, according to an example embodiment. The description of FIG. 8, which is the same as the descriptions of FIGS. 5 and 7, is omitted.

Referring to FIG. 8, an asymmetric scale may be formed of a plurality of vectors in one shot, and the asymmetric scale may be defined by the sum of the plurality of vectors. As described above, the asymmetric scale may include an X-axis skew Mag_X and a Y-axis skew Mag_Y. A magnitude of the asymmetric scale measured in operations S113 of operation S110 may be defined as 1. An asymmetric scale having a magnitude defined as 1 is described with reference to FIG. 9.

FIG. 9 is a conceptual view of a semiconductor device manufacturing method according to an example embodiment.

Together with FIGS. 1 to 8, FIG. 9 is a conceptual view illustrating the alignment of FIG. 8 by separating in two methods. Drawings in a first row may illustrate that only a scanner is aligned, and drawings in a second row may illustrate that the alignment further includes the reticle writing correction in operation S130 of FIG. 1 in addition to the alignment of the scanner.

For a substrate on which an exposure process is to be performed, an offset for each shot may be obtained by the scanner through operations S112 and S113. In this case, when comparing the first row in which only the scanner is aligned with the second row further including the reticle writing correction in operation S130 of FIG. 1 in addition to the alignment of the scanner, an amount of correction may be maintained. Accordingly, lengths of vectors of arrows of asymmetric scales for obtaining offsets for respective shots in the first row and the second row may be the same as each other.

After obtaining the offset for each shot, the asymmetric scale may be identified by performing operations S113 and S114. As mentioned with reference to FIG. 8, a magnitude of the asymmetric scale may be defined as 1, in the first row, an amount of alignment of the scanner may be the same as the magnitude of the asymmetric scale. Therefore, the amount of alignment of the scanner may be 1.

In the second row, a magnitude of the reticle writing correction may be x (wherein 0<x<1), and the amount of alignment of the scanner may be 1-x obtained by subtracting a value of the reticle writing correction from the magnitude of the asymmetric scale. In the second row, the amount of alignment of the scanner may be the same as a value of an alignment correction parameter that is fed forward in operation S142 of operation S140 of FIG. 3. Therefore, the value of the reticle writing correction may be less than the value of the asymmetric scale, and the sum of the value of the alignment correction parameter fed forward and the value of the reticle writing correction may be the same as the value of the asymmetric scale.

The value of the alignment correction parameter fed forward may be the same as the amount of alignment of the scanner, and the value of the alignment correction parameter fed forward and a skew value of a critical dimension may be proportional to each other. Therefore, when the amount of alignment of the scanner increases, the skew value of the critical dimension may increase. In an example embodiment, in the first row, a value of the amount of alignment of the scanner may be 1 and in the second row, the value of the amount of alignment of the scanner may be 1-x (wherein, 0<x<1), and thus, the value of the amount of alignment of the scanner in the first row may be greater than the value of the amount of alignment of the scanner in the second row. Therefore, the skew value of the critical dimension in the first row may be greater than the skew value of the critical dimension in the second row, and thus, a shape of the critical dimension in the first row may be longer in an elliptical shape than in the second row. In other words, the shape of the critical dimension in the second row may be closer to a circle than the shape of the critical dimension in the first row.

The rightmost drawings in the first row and the second row show correction values of a first layer and a second layer with arrows by using an overlay having a value of 0 as a reference line. For example, the same location at which the first layer and the second layer are is a point at which the overlay is 0, Thus, when the point at which the overlay of the first layer is 0 is determined, the second layer may be corrected up to a point at which the overlay is 0.

In the case of the first row in which only the scanner is aligned, the scanner may be aligned with respect to the second layer up to the point at which the overlay is 0.

When the reticle writing correction in operation S130 of FIG. 1 is further included in addition to the alignment of the scanner, the sum of the alignment of the scanner and the reticle writing correction may be corrected up to the point at which the overlay is 0. A magnitude of feedback performed by APC may be the same as the magnitude of the reticle writing correction, but a direction of the feedback may be different from a direction of the reticle writing correction. Therefore, FIG. 9 illustrates that after the scanner is aligned, the reticle writing correction is performed, and the feedback by the APC is performed, but the alignment of the scanner, the reticle writing correction, and the feedback may be performed simultaneously. Thus, an actual amount of alignment of the scanner may be a value obtained by subtracting a value of the feedback performed by the APC from the alignment of the scanner.

Therefore, the magnitude of alignment of the scanner in the second row may be less than the magnitude of alignment of the scanner in the first row, and accordingly, the skew value of the critical dimension in the second row may be less than the skew value of the critical dimension in the first row.

The reticle writing correction in the second row may correspond to the reticle writing correction applied to the mask in operation S130 of FIG. 1, and the feedback performed by the APC in the second row may correspond to operation S145 of FIG. 3.

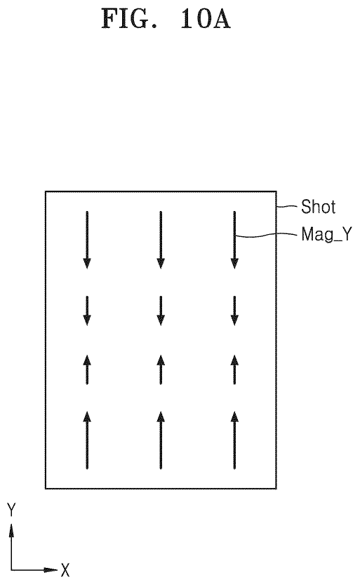

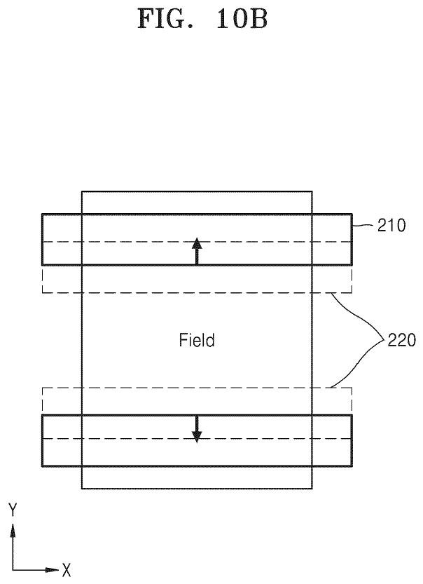

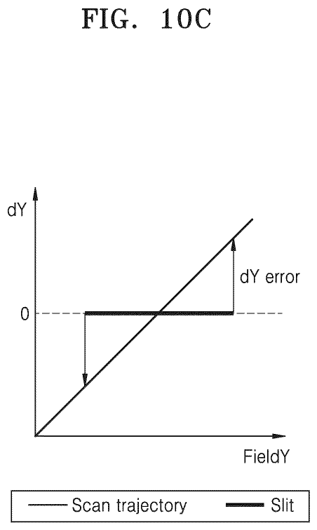

FIGS. 10A to 10C are views sequentially illustrating performing a Y-axis skew correction in a semiconductor device manufacturing method, according to an example embodiment.

Referring to FIG. 10A together with FIGS. 1 to 9, a Y-axis skew Mag_Y may occur in a virtual region shot measured by a scanner. The Y-axis skew Mag_Y may indicate that a shot is skewed upwards and downwards on the basis of an axis in a second direction Y. In more detail, the Y-axis skew Mag_Y may face each other toward a center of the shot in the second direction Y.

The scanner of FIGS. 1 to 3 may include a light source, an illuminator, a top module, a reticle, and projection optics. In addition, the reticle may be defined as a mask and disposed on a mask stage supporting the mask. The scanner may further include a substrate stage supporting a substrate.

Referring to FIG. 10B together with FIGS. 1 to 10A, a correction of the Y-axis skew Mag_Y may be performed on the mask stage supporting the mask and the substrate stage supporting the substrate. The scanner may include a slit. In an example embodiment, the slit may have a thickness of about 3.4 mm, but is not limited thereto. A residual into the second direction Y may be generated due to the thickness of the slit. The slit may perform a scan while moving above a field in the second direction Y. An actual location 220 of the slit is indicated a dotted line. When performing the scan at the actual location 220, the Y-axis skew Mag_Y may occur in the second direction Y to face each other, and thus, the slit may obtain the substantially same result as performing the scan at a scan location 210 indicated by a solid line.

In an example embodiment, when viewing the field of FIG. 10B as the center, a slit above a central axis of the field is described. Referring to FIG. 10A, the Y-axis skew Mag_Y at a corresponding location may face downwards. Therefore, even though the slit is located at the actual location 220 indicated by the dotted line, when performing the scan, the Y-axis skew Mag_Y, which faces downwards, may result in scanning the scan location 210 indicated by the solid line, which is above the actual location 220.

In an example embodiment, when viewing the field of FIG. 10B as the center, the slit below the central axis of the field is described. Referring to FIG. 10A, the Y-axis skew Mag_Y at a corresponding location may face upwards. Therefore, even though the slit is located at the actual location 220 indicated by the dotted line, when performing the scan, the Y-axis skew Mag_Y, which faces upwards, may result in scanning the scan location 210 indicated by the solid line, which is below the actual location 220.

FIG. 1C is a graph illustrating a situation of FIG. 10B. Referring to FIG. 10C together with FIGS. 1 to 10B, Field Y on an X axis may indicate a moving direction of a slit. dY on a Y axis may indicate a value at which the slit is skewed in a second direction Y. In an example embodiment, dY may indicate that in the case below 0, a scan is performed in a direction −Y further down an actual location. In an example embodiment, dY may indicate that in the case above 0, the scan is performed in a direction+Y further up the actual location. Referring to the graph, when the slit is located at 0, a positive error (+Y) may occur when FieldY increases, and a negative error (−Y) may occur when FieldY decreases. Both the positive error and the negative error may be defined as dY errors. To reduce the dY error, a magnitude of the dY error for each field Y may be calculated and the scan may be performed by pre-aligning the slit in the second direction Y. In some example embodiments, a portion of a pre-alignment value of the slit may be corrected through the reticle writing correction in operation 130 of FIG. 1.

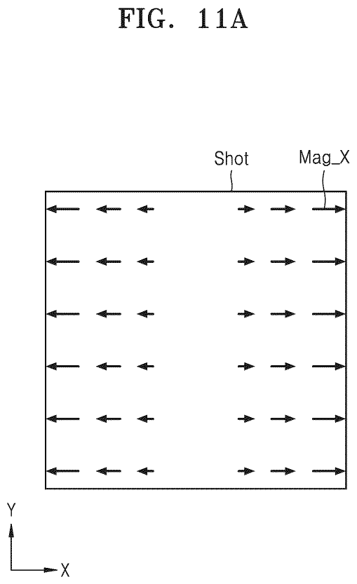

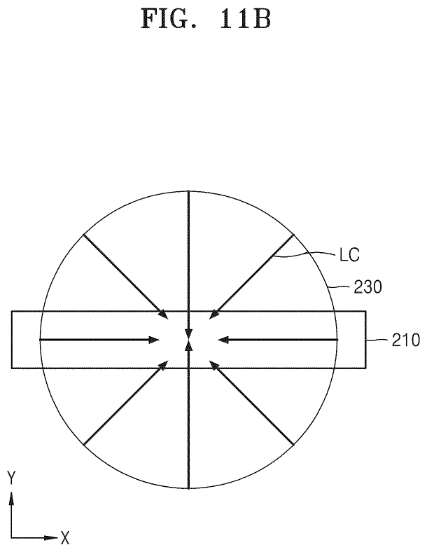

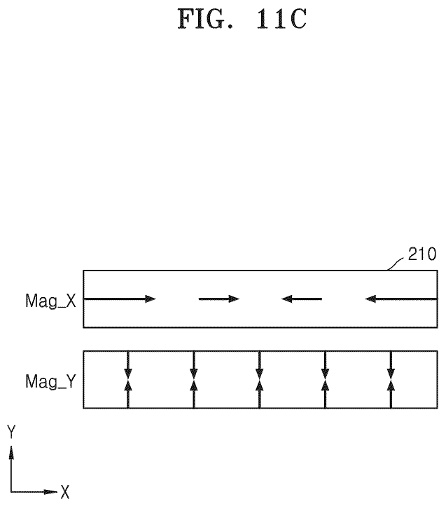

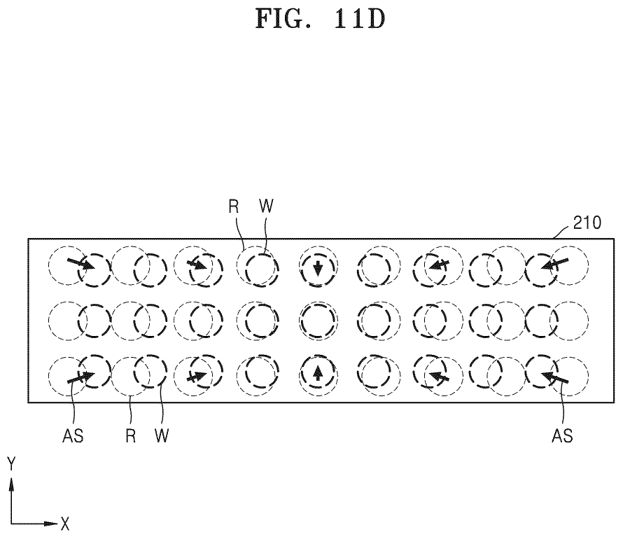

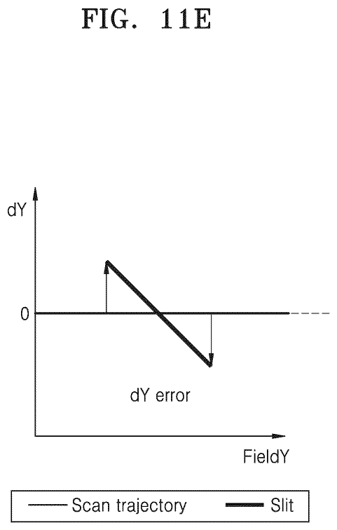

FIGS. 11A to 11E are views sequentially illustrating performing an X-axis skew correction in a semiconductor device manufacturing method, according to an example embodiment.

Referring to FIG. 11A together with FIGS. 1 to 10C, a correction of an X-axis skew Mag_X may be performed by projection optics arranged between a mask stage and a substrate stage. In an example embodiment, the projection optics may include a lens. The X-axis skew Mag_X may occur inside a virtual region shot measured by a scanner. The X-axis skew Mag_X may indicate that the virtual region shot is skewed to the left and right on the basis of a central axis of a first direction X. For example, the virtual region shot may be skewed opposed to each other with respect to the central axis in the first direction X.

Referring to FIG. 11B together with FIGS. 1 to 11A, a lens 230 may be used to correct the X-axis skew Mag_X in which the virtual region shot is skewed opposed to each other on the basis of the central axis in the first direction X. The lens 230 may perform lens correction LC for focusing light toward a central axis thereof. A scan location 210 of a slit may be the same as an actual location. In the case of the correction of the X-axis skew Mag_X, the slit may not move and only the lens 230 may be used. Therefore, the scan location 210 may be the same as the actual location.

Referring to FIG. 11C together with FIGS. 1 to 11B, an X-axis skew Mag_X and a Y-axis skew Mag_Y may occur on the basis of a location of the slit due to the lens correction LC in which the lens 230 focuses light toward the central axis thereof. In more detail, the X-axis skew Mag_X occurring by the lens 230 may occur in a direction facing each other on the basis of the central axis of the slit in the first direction X. Similarly, the Y-axis skew Mag_Y occurring by the lens 230 may occur in a direction facing each other on the basis of a central axis of the slit in a second direction Y.

Thus, the lens 230, which performs the lens correction LC to correct the X-axis skew Mag_X, may be used, but the lens correction LC may enable only a symmetrical correction. Therefore, when the X-axis skew Mag_X is corrected, the Y-axis skew Mag_Y, which is not scheduled to be corrected, may be corrected at once and accordingly, the Y-axis skew Mag_Y may occur within the slit by the lens 230.

FIG. 11D may be referred to together with FIGS. 1 to 11C. A reticle R may be skewed at a scan location 210 of the slit, and an exposure reflecting such skew may be performed at a location of a substrate W.

When a correction is performed on the X-axis skew Mag_X, as shown in FIG. 11C, the reticle R may be formed in a direction in which the reticle R converges toward the center in both the first direction X and the second direction Y.

Referring to FIG. 11E together with FIGS. 1 to 11D, a value of dY indicating a correction value in the second direction Y with respect to a scan trajectory may be constant as 0. In other words, the slit may not move in the second direction Y. The slit may not move, but as described above, the Y-axis skew Mag_Y may occur in a process of correcting the X-axis skew Mag_X. Referring to the graph, when the slit is located at 0, a negative error −Y may occur with an increase in FieldY, and a positive error+Y may occur with a decrease in FieldY. Both the positive error and the negative error may be defined as dY errors. To reduce the dY error, a magnitude of the dY error for each field Y may be calculated and the scan may be performed by pre-aligning the slit in the second direction Y. In some example embodiments, a portion of a pre-alignment value of the slit may be corrected through the reticle writing correction in operation 130 of FIG. 1.

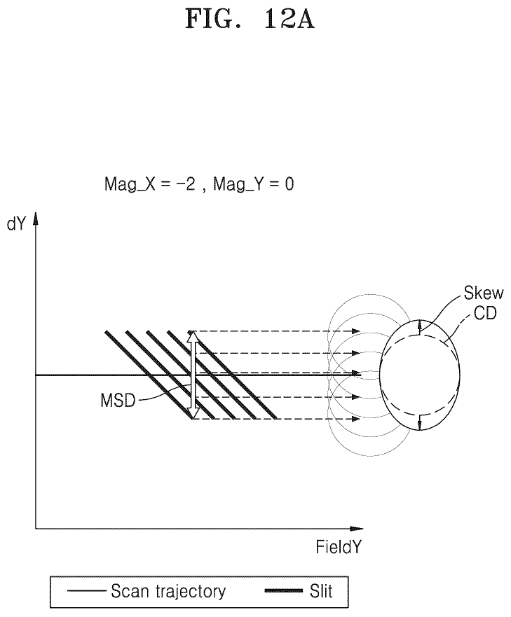

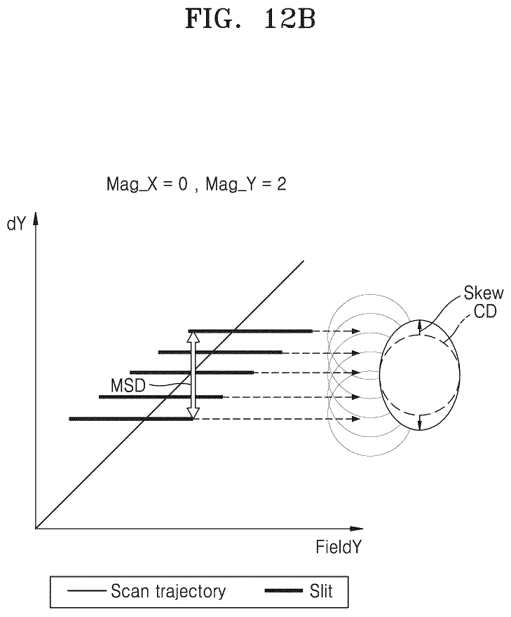

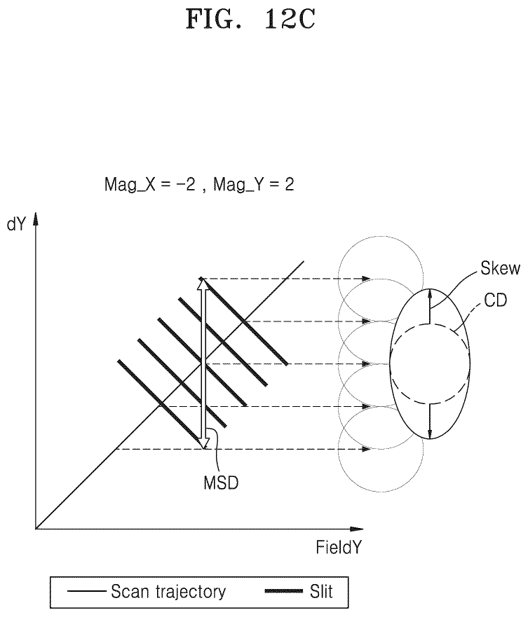

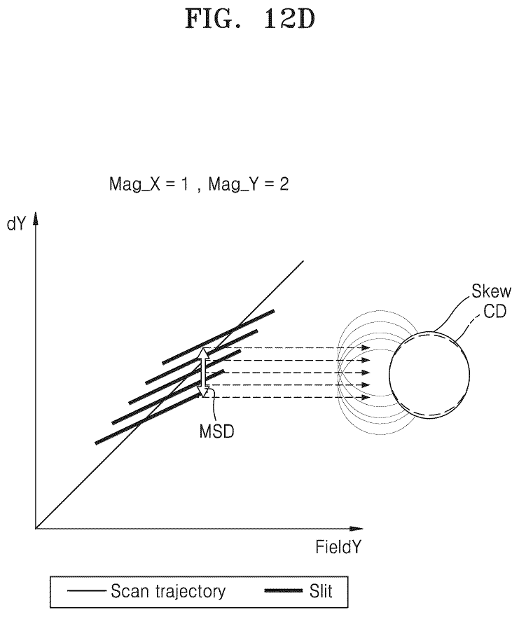

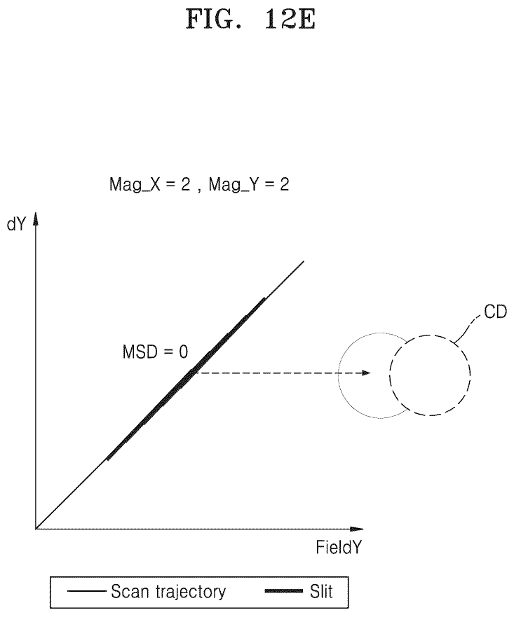

FIGS. 12A to 12E are views illustrating a skew value of a critical dimension with respect to a moving standard deviation.

A deviation from a direction in which a slit moves along a scan trajectory of a scanner may be defined as a moving standard deviation (MSD). A magnitude of the MSD may vary according to a combination of an X-axis skew Mag_X and a Y-axis skew Mag_Y.

Referring to FIG. 12A, a magnitude of the X-axis skew Mag_X may be −2, and a magnitude of the Y-axis skew Mag_Y may be 0. In other words, the Y-axis skew Mag_Y may not occur, and the X-axis skew Mag_X, which tends to move away from each other on basis of a central axis in a first direction X, may occur. The Y-axis skew Mag_Y may not occur, and thus, as shown in FIG. 11E, a dY value of the scan trajectory of the slit may be constant as 0. A gradient of the slit is also as shown in FIG. 11E. For the leftmost slit, a negative error −Y may occur on the basis of 0 that is the dY value. Therefore, a scan may be performed downwards by an absolute value of the negative error −Y on the basis of a region indicated by a dotted line, which is a normal value of a critical dimension. For the rightmost slit, a positive error+Y may occur on the basis of 0 that is a dY value. Therefore, the scan may be performed upwards by the absolute value of the negative error −Y on the basis of the region indicated by the dotted line, which is the normal value of the critical dimension. For a slit located in the middle, an error may not occur on the basis of 0 that is the dY value. Therefore, the region indicated by the dotted line, which is the normal value of the critical dimension, may be scanned. Accordingly, when results of scanning the slit are integrated, a skew may occur as much as the negative error −Y and the positive error+Y. After measuring the skew in operation S160 of FIG. 1, the skew may be corrected through the feedback in operations S130 and/or S140.

Referring to FIG. 12B, the magnitude of the X-axis skew Mag_X may be 0, and the magnitude of the Y-axis skew Mag_Y may be 2. In other words, the X-axis skew Mag_X may not occur, and the Y-axis skew Mag_Y, which faces each other and tends to be closer to each other on the basis of a central axis in a second direction Y, may occur. The X-axis skew Mag_X may not occur, and thus, the dY value of the slit may be constant as 0 as shown in FIG. 10C, and a gradient of a scan trajectory of the slit may be also as shown in FIG. 10C. For the leftmost slit, the negative error −Y may occur on the basis of 0 that is the dY value. Therefore, a scan may be performed downwards by the absolute value of the negative error −Y on the basis of the region indicated by the dotted line, which is the normal value of the critical dimension. For the rightmost slit, the positive error+Y may occur on the basis of 0 that is the dY value. Therefore, the scan may be performed upwards by the absolute value of the negative error −Y on the basis of the region indicated by the dotted line, which is the normal value of the critical dimension. For the slit located in the middle, an error may not occur on the basis of the dY value of 0. Therefore, the region indicated by the dotted line, which is the normal value of the critical dimension, may be scanned. Accordingly, when results of scanning the slit are integrated, the skew may occur as much as the negative error −Y and the positive error+Y. The magnitude of the skew occurring in FIG. 12B may be the same as the magnitude of the skew occurring in FIG. 12A.

Referring to FIG. 12C, the magnitude of the X-axis skew Mag_X may be −2, and the magnitude of the Y-axis skew Mag_Y may be 2. In other words, the X-axis skew Mag_X, which tends to move away from each other on the basis of a central axis in a first direction X, and the Y-axis skew Mag_Y, which faces each other and tends to be closer to each other on the basis of the central axis in the second direction Y, may occur. The X-axis skew Mag_X may be −2, and thus, the slit may have a gradient as shown in FIG. 11E. The magnitude of the Y-axis skew Mag_Y may be 2, and thus, the scan trajectory may have a gradient as shown in FIG. 10C. For the leftmost slit, the negative error −Y may occur on the basis of 0 that is the dY value. Therefore, the scan may be performed downwards by the absolute value of the negative error −Y on the basis of the region indicated by the dotted line, which is the normal value of the critical dimension. For the rightmost slit, the positive error+Y may occur on the basis of 0 that is the dY value. Therefore, the scan may be performed upwards by the absolute value of the negative error −Y on the basis of the region indicated by the dotted line, which is the normal value of the critical dimension. For the slit located in the middle, an error may not occur on the basis of the dY value of 0. Therefore, the region indicated by the dotted line, which is the normal value of the critical dimension, may be scanned. Accordingly, when results of scanning the slit are integrated, the skew may occur as much as the negative error −Y and the positive error+Y. The negative error −Y and the positive error+Y in FIG. 12C may be greater than the negative error −Y and the positive error+Y in FIGS. 12A and 12B, and thus, the skew occurring in FIG. 12C may be greater than the skew in FIGS. 12A and 12B.

Referring to FIG. 12D, the magnitude of the X-axis skew Mag_X may be 1, and the magnitude of the Y-axis skew Mag_Y may be 2. In other words, the X-axis skew Mag_X, which faces each other and tends to be closer to each other on the basis of the central axis in the first direction X, and the Y-axis skew Mag_Y, which faces each other and tends to be closer to each other on the basis of the central axis in the second direction Y, may occur. The X-axis skew Mag_X may be 1, and thus, the slit may have a gradient that is in an opposite direction to and less than the gradient of the slit in FIG. 11E. The magnitude of the Y-axis skew Mag_Y may be 2, and thus, the scan trajectory may have a gradient as shown in FIG. 10C. For the leftmost slit, the negative error −Y may occur on the basis of 0 that is the dY value. Therefore, the scan may be performed downwards by the absolute value of the negative error −Y on the basis of the region indicated by the dotted line, which is the normal value of the critical dimension. For the rightmost slit, the positive error+Y may occur on the basis of 0 that is the dY value. Therefore, the scan may be performed upwards by the absolute value of the negative error −Y on the basis of the region indicated by the dotted line, which is the normal value of the critical dimension. For the slit located in the middle, an error may not occur on the basis of the dY value of 0. Therefore, the region indicated by the dotted line, which is the normal value of the critical dimension, may be scanned. Accordingly, when results of scanning the slit are integrated, the skew may occur as much as the negative error −Y and the positive error+Y. The negative error −Y and the positive error+Y in FIG. 12D may be less than the negative error −Y and the positive error+Y in FIGS. 12A and 12B, and thus, the skew occurring in FIG. 12D may be less than the skew in FIGS. 12A and 12B.

Referring to FIG. 12E, the magnitude of the X-axis skew Mag_X may be 2, and the magnitude of the Y-axis skew Mag_Y may be 2. In other words, the X-axis skew Mag_X, which faces each other and tends to be closer to each other on the basis of the central axis in the first direction X, and the Y-axis skew Mag_Y, which faces each other and tends to be closer to each other on the basis of the central axis in the second direction Y, may occur. The X-axis skew Mag_X may be 2, and thus, the slit may have a gradient that is in an opposite direction to and the same as the gradient of the slit in FIG. 11E. The magnitude of the Y-axis skew Mag_Y may be 2, and thus, the scan trajectory may have a gradient as shown in FIG. 10C. For all slits, an error may not occur on the basis of 0 that is the dY value. Therefore, the region indicated by the dotted line, which is the normal value of the critical dimension, may be scanned, and a value of an MSD may be 0. A skew of the critical dimension may not occur. FIG. 12E illustrates a situation after being corrected by operations S110 to S170 of FIG. 1. Operations S110 to S170 of FIG. 1 may be repeatedly performed so that FIGS. 12A to 12D in which the MSD occurs becomes the situation as in FIG. 12E.

According to some example embodiments, a scanner may insert corrections into a reticle in advance through a reticle writing correction (RWC) to reduce a rate of alignment of the scanner and thus may reduce a CD skew, instead of performing perform all of corrections of an asymmetric scale for each shot to correct alignment.

Any method operations shown in the figures and described above may be performed by processing circuitry such as hardware including logic circuits, a hardware/software combination such as a processor executing software, or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

While the inventive concepts have been particularly shown and described with reference to some example embodiments thereof, it will be understood that various changes in form and details may be made therein without departing from the spirit and scope of the following claims.

What is claimed is:

1. A semiconductor device manufacturing method comprising:
determining whether or not a reticle writing correction needs to be applied to a mask for an exposure process;
when determining that the reticle writing correction needs to be applied, manufacturing the mask to which the reticle writing correction is applied;
by using the mask to which the reticle writing correction is applied, measuring an overlay and performing a correction based on the overlay;
determining whether or not a value of the overlay is greater than a specification; and
when the value of the overlay is not greater than the specification, performing a subsequent process.

2. The semiconductor device manufacturing method of claim 1, wherein the determining of whether or not the reticle writing correction needs to be applied comprises:
performing a first alignment with respect to a scanner;
performing a first exposure on a substrate through the scanner that has been aligned by performing the first alignment;
measuring an alignment correction parameter while the scanner performs the first exposure on the substrate;
identifying an asymmetric scale from the alignment correction parameter;
determining whether or not the identified asymmetric scale is greater than the specification; and
when the asymmetric scale is greater than the specification, determining that the reticle writing correction needs to be applied to the mask for the exposure process.

3. The semiconductor device manufacturing method of claim 2, wherein the determining of whether or not the reticle writing correction needs to be applied further comprises:
when the asymmetric scale is not greater than the specification, determining that the reticle writing correction does not need to be applied to the mask for the exposure process; and
when determining that the reticle writing correction does not need to be applied, mounting, on the substrate, the mask to which the reticle writing correction is not applied.

4. The semiconductor device manufacturing method of claim 2, wherein, when a value of the asymmetric scale is defined as 1, a magnitude of the reticle writing correction is x (where 0<x<1).

5. The semiconductor device manufacturing method of claim 2, wherein the measuring of the overlay and performing of the correction based on the overlay comprises:
performing a second alignment with respect to the scanner;
feeding forward the alignment correction parameter to the scanner;
performing a second exposure on the substrate through the scanner that has been fed forward the alignment correction parameter; and
measuring the overlay through the scanner.

6. The semiconductor device manufacturing method of claim 5, wherein the measuring of the overlay and performing of the correction based on the overlay further comprises, when the value of the overlay is greater than the specification, feeding an overlay correction value back to the scanner so that the value of the overlay is less than the specification.

7. The semiconductor device manufacturing method of claim 1, further comprising:
when the value of the overlay is not greater than the specification, measuring a skew value of a critical dimension through a scanner;
determining whether or not the skew value of the critical dimension is greater than the specification; and
when the skew value of the critical dimension is not greater than the specification, performing a subsequent process.

8. The semiconductor device manufacturing method of claim 7, wherein, when the skew value of the critical dimension is greater than the specification, the manufacturing of the mask to which the reticle writing correction is applied is re-performed.

9. The semiconductor device manufacturing method of claim 7, wherein, when the critical dimension is defined as a size of a hole in a substrate, the skew value is a difference in an aspect ratio of the hole.

10. The semiconductor device manufacturing method of claim 1, further comprising:
when the value of the overlay is greater than the specification, re-performing the measuring of the overlay and performing of the correction based on the overlay through the mask to which the reticle writing correction is applied.

11. A semiconductor device manufacturing method comprising:
performing a first alignment with respect to a scanner configured to perform an exposure process on a substrate;
performing a first exposure on the substrate through the scanner that has been aligned by performing the first alignment;
measuring an alignment correction parameter while the scanner performs the first exposure on the substrate;
identifying an asymmetric scale from the alignment correction parameter;
determine whether or not the identified asymmetric scale is greater than a specification;
when the asymmetric scale is greater than the specification, determining that a reticle writing correction needs to be applied to a mask for an exposure process and manufacturing the mask to which the reticle writing correction is applied;
measuring an overlay and performing a correction based on the overlay through the mask to which the reticle writing correction is applied;
determining whether or not a value of the overlay is greater than the specification;
when the value of the overlay is not greater than the specification, measuring a skew value of a critical dimension through the scanner;
determining whether or not the skew value of the critical dimension is greater than the specification; and
when the skew value of the critical dimension is not greater than the specification, performing a subsequent process,
wherein, when viewed on a plane, the asymmetric scale includes Y-axis skews facing each other toward a central axis of the substrate in a first direction and X-axis skews opposing each other and moving away from a central axis in a second direction orthogonal to the first direction.

12. The semiconductor device manufacturing method of claim 11, wherein, the measuring of the overlay and performing of the correction based on the overlay comprises:
performing a second alignment with respect to the scanner;
feeding forward the alignment correction parameter to the scanner;
performing a second exposure on the substrate through the scanner that has been fed forward the alignment correction parameter; and
measuring the overlay through the scanner.

13. The semiconductor device manufacturing method of claim 11, wherein a value of the reticle writing correction is less than a value of the asymmetric scale, and a sum of a value of the alignment correction parameter fed forward and the value of the reticle writing correction is same as the value of the asymmetric scale.

14. The semiconductor device manufacturing method of claim 12, wherein the substrate comprises at least two layers, and the first alignment and the second alignment performed with respect to the scanner are performed on a same layer.

15. The semiconductor device manufacturing method of claim 12, wherein the value of the alignment correction parameter fed forward is proportional to the skew value of the critical dimension.

16. The semiconductor device manufacturing method of claim 11, wherein, when viewed on a plane, when a partial region of the substrate is defined as a shot, the scanner scans the substrate for each of a plurality of shots, and the asymmetric scale is a vector value measured for each shot.

17. The semiconductor device manufacturing method of claim 12, wherein
the reticle writing correction includes a correction of the Y-axis skews and a correction of the X-axis skews,
the correction of the Y-axis skews is performed on a mask stage supporting the mask and a substrate stage supporting the substrate,
the correction of the X-axis skews is performed by a lens arranged between the mask stage and the substrate stage, and
the correction of the Y-axis skews and the correction of the X-axis skews are performed independently of each other.

18. The semiconductor device manufacturing method of claim 17, wherein
the scanner comprises a slit, and
when a deviation from a direction in which the slit moves along a scan trajectory of the scanner is defined as a moving standard deviation, the reticle writing correction is an operation configured to reduce the moving standard deviation.

19. A semiconductor device manufacturing method comprising:
determining whether or not a reticle writing correction needs to be applied to a mask for an exposure process;
when determining that the reticle writing correction needs to be applied, manufacturing the mask to which the reticle writing correction is applied;
measuring an overlay and performing a correction based on the overlay through the mask to which the reticle writing correction is applied;
determining whether or not a value of the overlay is greater than a specification;
when the value of the overlay is not greater than the specification, measuring a skew value of a critical dimension;
determining whether or not the skew value of the critical dimension is greater than the specification; and
when the skew value of the critical dimension is not greater than the specification, performing a subsequent process,
wherein the determining of whether or not the reticle writing correction needs to be applied comprises
performing a first alignment with respect to a scanner,
performing a first exposure on a substrate through the scanner that has been aligned by performing the first alignment,
measuring an alignment correction parameter while the scanner performs the first exposure on the substrate,
identifying an asymmetric scale from the alignment correction parameter,
determining whether or not the identified asymmetric scale is greater than the specification, and
when the asymmetric scale is greater than the specification, determining that the reticle writing correction needs to be applied to the mask for the exposure process,
the measuring of the overlay and performing of the correction based on the overlay comprises
performing a second alignment with respect to the scanner,
feeding forward the alignment correction parameter to the scanner,
performing a second exposure on the substrate through the scanner that has been fed forward the alignment correction parameter, and
measuring the overlay through the scanner, and
when a value of the asymmetric scale is defined as 1, a magnitude of the reticle writing correction is x (wherein 0<x<1), and a value of the alignment correction parameter fed forward to the scanner is 1-x.

20. The semiconductor device manufacturing method of claim 19, further comprising:
when determining that the reticle writing correction does not need to be applied, mounting, on the substrate, the mask to which the reticle writing correction is not applied;
when the value of the overlay is greater than the specification, re-performing the measuring of the overlay and performing of the correction based on the overlay through the mask to which the reticle writing correction is applied; and
when the skew value of the critical dimension is greater than the specification, re-performing the manufacturing of the mask to which the reticle writing correction is applied,
wherein the determining of whether or not the reticle writing correction needs to be applied comprises, when the asymmetric scale is not greater than the specification, determining that the reticle writing correction does not need to be applied to the mask for the exposure process, and
wherein the measuring of the overlay and performing of the correction based on the overlay comprises, when the value of the overlay is greater than the specification, feeding an overlay correction value back to the scanner.
